(19) United States
(12) Patent Application Publication
(10) Pub. No.: US 2011/0089524 A1
(43) Pub. Date: Apr. 21, 2011

(54) SEMICONDUCTOR DEVICE AND METHOD OF MANUFACTURING THE SAME

(75) Inventor: Yoshihisa NONOGAKI, Tokyo (JP)

(73) Assignee: SUMCO CORPORATION, Tokyo (JP)

(21) Appl. No.: 12/903,386

(22) Filed: Oct. 13, 2010

(30) Foreign Application Priority Data
Oct. 16, 2009 (JP) 2009-239673

(51) Int. Cl. H01L 29/02; H01L 21/762

(52) U.S. Cl. 257/506; 438/459; 257/E21.567; 257/E29.002

(57) ABSTRACT

A semiconductor device and a method of manufacturing the same capable of reducing variations in the thickness of a semiconductor device are provided. The amount of oxygen implanted ions is less than the amount of implanted oxygen ions in the conventional epitaxial SIMOX wafers. Oxygen is ion-implanted into the surface layer of a silicon wafer from the surface of the wafer. Then, by heat treating the wafer, a thinning stop layer, which is an imperfect buried oxide film, is formed along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

### BACKGROUND OF THE INVENTION

1. Field of the Invention

The present invention relates to a semiconductor device and a method of manufacturing the same. More specifically, it relates to a semiconductor device formed on a silicon wafer that is required to be thinned, and a method of manufacturing the same.

Priority is claimed on Japanese Patent Application No. 2009-239673, filed Oct. 16, 2009, the content of which is incorporated herein by reference.

2. Description of Related Art

For example, in a frontside illuminated CMOS solid-state imaging sensor, which is one of semiconductor device, multilayer interconnections exist in a path of light to be irradiated, particularly, in the light path of angled light in the peripheral portion of the effective pixel area. It is known that the sensitivity of the device is reduced because of a low usage of light resulted from the obstruction of the penetrating light by the multilayer interconnections. Consequently, as the related art for solving the above-mentioned problem, a backside illuminated CMOS solid-state imaging sensor, in which the multilayer interconnections are formed on the surface side of the wafer and light is irradiated from its backside, has been developed (Japanese Unexamined Patent Application Publication No. 2008-258201).

To manufacture this backside illuminated CMOS solid-state imaging sensor, first, a solid-state imaging sensor (semiconductor device) is formed in the surface layer of the silicon wafer, and then, a support substrate is bonded to the surface of the silicon wafer to produce a bonded wafer. Next, the silicon wafer is thinned from its backside until only a portion in the vicinity of the solid-state imaging sensor remains. Then, a color filter and an on-chip lens are sequentially formed on the thinned surface of the silicon wafer. With the process described above, the backside illuminated CMOS solid-state imaging sensor is manufactured.

In regard to thinning of the silicon wafer, it has been demanded recently to reduce the variation of thickness of the solid-state imaging sensor from the viewpoint of device manufacturing.

As the related art for coping with this problem, for example, a method is developed, in which the surface layer of the wafer is locally dry-etched, a plurality of deep trenches are formed with a predetermined interval, and a material different from that of the silicon wafer is deposited and used as an end point detector, as disclosed in Japanese Unexamined Patent Application Publication No. 2005-353996. At the thinning in the method described above, an end point of the thinning (delimitation position) by grinding, polishing and plasma etching of the silicon wafer is detected by the end point detector, and variations of the thickness of the solid-state imaging sensor are reduced. With variations in the thickness of the solid-state imaging sensor, it may cause inconsistent incident intensity of light with respect to each CMOS solid-state imaging sensor, generating uneven color.

However, in the method of thinning the silicon wafer using the end point detector having the deep trench structure as disclosed in Japanese Unexamined Patent Application Publication No. 2005-353996, the amount of dry etching for the surface layer of the wafer is not uniform because accuracy of the apparatus used for forming the deep trench is low, resulting in deep trenches with varied depths Moreover, although each of the end point detectors having the deep trench structure is arranged along the entire silicon wafer at a predetermined pitch in a matrix shape, it is merely provided locally within the wafer surface. As a result, in thinning of the silicon wafer by Japanese Unexamined Patent Application Publication No. 2005-353996, the, the reliability of the accuracy of the end point is low, and variations in the thickness of the solid-state imaging sensor in the CMOS solid-state imaging sensor are large.

As a result of studying assiduously, the inventor has perceived that by forming an imperfect buried oxide film having a mixture of a silicon grain and a silicon oxide in the surface layer of the wafer with ion implantation of oxygen from the surface of the silicon wafer, and by using the imperfect buried oxide film as a new thinning stop layer, which is different from the end point detector having the deep trench structure of the related art, the above-mentioned problems are fully solved, and thus has completed the invention.

The invention provides a semiconductor device and a method of manufacturing the same capable of reducing variations in the thickness of the semiconductor device.

### SUMMARY OF THE INVENTION

A method of manufacturing a semiconductor device according to one aspect of the invention includes: a step of ion-implanting, in which oxygen ions are implanted from a surface of a silicon wafer to form an ion-implanted layer in the surface layer of the silicon wafer; a step of heat-treating and film forming, in which the ion-implanted layer is heat treated and an epitaxial film is formed on the surface of the silicon wafer, after the step of ion-implanting; a step of forming a semiconductor device, in which a semiconductor device is formed in the epitaxial film, after the step of heat-treating and film forming; a step of bonding, in which a support substrate is bonded on the surface of the epitaxial film to produce a bonded wafer, after the step of forming a semiconductor device; and a step of thinning, in which the bonded wafer is thinned from a back side of the silicon wafer, by at least one of grinding, polishing, and wet-etching until a remaining thickness thereof to be 10 to 100 μm, and then further thinned by dry-etching as a finishing process. In the step of heat-treating and film forming, a thinning stop layer having a mixture of a silicon grain and a silicon oxide is formed along the entire plane of the wafer, and an active layer is formed between a surface side of the silicon wafer and the thinning stop layer.

According to the above-mentioned aspect, in the ion-implanting step, the amount of oxygen ions implanted into the surface layer of the silicon wafer is less than that for the production of a conventional epitaxial SIMOX wafer, and the heat treatment (annealing) of the ion-implanted layer after the step of ion-implanting is performed at a lower temperature than a high temperature for annealing for the epitaxial SIMOX wafer in the heat-treating. Thus, the thinning stop layer is formed in the surface layer of the silicon wafer along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

After that, the semiconductor device is formed in the epitaxial film, and then, the support substrate is bonded to the surface of the epitaxial film, producing the bonded wafer. After bonding, the silicon wafer is thinned from a back side of the silicon wafer, by at least one of grinding, polishing, and wet-etching until a remaining thickness thereof to be 10 to 100 μm and then further thinned by dry-etching as a finishing process.

In addition, in the step of heat-treating and film forming, the epitaxial film may be formed after the heat treatment of the ion-implanted layer.

According to the above-mentioned aspect, in the step of ion-implanting, the amount of oxygen ions implanted into the surface layer of the silicon wafer is less than the amount of oxygen implanted in a conventional epitaxial SIMOX wafer, and the heat treatment (annealing) of the ion-implanted layer after the step of ion-implanting is performed at a lower temperature than a high temperature for annealing for the epitaxial SIMOX wafer in the heat-treating. Thus, the thinning stop layer is formed in the surface layer of the silicon wafer along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

After that, the semiconductor device is formed in the epitaxial film, and then, the support substrate is bonded to the surface of the epitaxial film, producing the bonded wafer. After bonding, the silicon wafer is thinned from a back side of the silicon wafer, by at least one of grinding, polishing, and wet-etching until the remaining thickness thereof to be 10 to 100 μm and then further thinned by dry-etching as a finishing process.

In this case, the heat treatment is performed after the step of ion-implanting, and after the heat treatment, an epitaxial film is grown. Therefore, oxygen precipitated by the heat treatment functions as a gettering site, resulting in formation of a high-quality epitaxial film.

In addition, in the step of heat-treating and film forming, the heat treatment of the ion-implanted layer and the formation of the epitaxial film may be performed concurrently.

According to the above-mentioned aspect, in the ion-implanting step, the amount of oxygen ions implanted into the surface layer of the silicon wafer is less than that for the production of a conventional epitaxial SIMOX wafer, and the heat treatment (annealing) of the ion-implanted layer is performed at a lower temperature than a high temperature for annealing for the epitaxial SIMOX wafer in the heat-treating concurrently with the formation of the epitaxial film. Thus, the thinning stop layer is formed in the surface layer of the silicon wafer along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

After that, the semiconductor device is formed in the epitaxial film, and then, the support substrate is bonded to the surface of the epitaxial film, producing the bonded wafer. After bonding, the silicon wafer is thinned from the back side of the silicon wafer, by at least one of grinding, polishing, and wet-etching until a remaining thickness thereof to be 10 to 100 μm and then further thinned by dry-etching as a finishing process.

In addition, in the step of heat-treating and film forming, the ion-implanted layer may be heat-treated after the epitaxial film is formed.

According to the above-mentioned aspect, the silicon wafer is annealed (heat treated) after the epitaxial growth of the film, in addition to heat treatment in the device process. Therefore, the thinning stop layer is formed in the surface layer of the silicon wafer along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

The heating temperature and the heat treatment time of the wafer in the annealing for the above-mentioned aspect are the same as those for the other aspects of the present invention mentioned above.

In the step of ion-implanting, the silicon wafer may be heated at a temperature of 200° C. or higher, and the amount of implanted oxygen ions may be in a range of 1×10¹⁵ atoms/cm² to 4×10¹⁷ atoms/cm².

When the heating temperature of the wafer in the step of ion-implanting is less than 200° C., damages formed during oxygen ion-implanting into the surface layer of the wafer remain and cannot be removed. It is preferable to perform the heating in the step of ion-implanting at a temperature ranged from 300° C. to 600° C. In addition, the amount of precipitated oxygen can be increased by performing the oxygen ion-implanting at a low temperature ranged from 200 to 300° C. The same effect can be achieved by performing the oxygen ion-implanting twice. When the amount of oxygen ions implanted in the step of ion-implanting is less than 1×10¹⁵ atoms/cm², the thinning stop layer does not function as an end point detector in the step of thinning the silicon wafer. In addition, when the amount exceeds 4×10¹⁷ atoms/cm², it takes a long period of time to implant the oxygen ions. Consequently, the productivity of the epitaxial wafer decreases, and the production cost increases.

In the step of heat-treating and film forming, the silicon wafer may be heat-treated at a temperature of 900° C. to 1200° C. for a time of from thirty seconds to four hours.

When the heat treatment temperature is lower than 900° C., the amount of precipitated oxygen is low. In addition, when the heat treatment temperature exceeds 1200° C., a special annealing furnace for ultra-high temperature heat treatment is needed. The heat treatment temperature of the silicon wafer is preferably in a range of 1100° C. to 1200° C. in which precipitation of oxygen is formed at a higher rate.

When the heat treatment time is less than 30 seconds, the amount of precipitated oxygen is low. In addition, when the heat treatment time exceeds 4 hours, the productivity of the epitaxial wafer decreases, and the production cost increases. The preferable time for heat-treating the silicon wafer ranges from 5 minutes to 4 hours. Under the conditions, the, the reliability of the end point during thinning by precipitated oxygen increases. An even more preferable time for heat-treating the silicon wafer renges from 10 minutes to 1 hour. Under these conditions, the reliability of the end point during thinning by precipitated oxygen increases, and at the same time, the productivity also increases.

The thinned semiconductor device according to another aspect of the invention includes: a silicon wafer; a thinning stop layer, which has a mixture of a silicon grain and a silicon oxide and is formed along the entire plane of the wafer in the surface layer of the silicon wafer, by implanting oxygen ions into the silicon wafer from the surface thereof, and then heat-treating the silicon wafer; an active layer formed between the surface side of the silicon wafer and the thinning stop layer; an epitaxial film formed on the surface side of the active layer; a semiconductor device formed in the epitaxial film; and a support substrate bonded to the surface of the epitaxial film, wherein the silicon wafer is thinned from the back side of the silicon wafer, by at least one of grinding, polishing, and wet-etching until the thickness thereof is 10 to 100 μm, and then further thinned by dry-etching as a finishing process.

According to the above-mentioned semiconductor device, the thinning stop layer is formed along the entire plane of the wafer, by implanting oxygen ions and subsequent heat-treating, in the surface layer of the silicon wafer having an epitaxial film. The thinning stop layer is an imperfect buried oxide film having a mixture of silicon grains and the silicon oxide. Because of this, the, the reliability of the accuracy of the end point of silicon wafer thinning is higher than that of a thinning using the conventional deep trench structure as an end point detector. As a result, variation of the thickness of the semiconductor device formed in an active layer can be reduced.

According to the method of manufacturing the semiconductor device and the semiconductor device of the present invention, the amount of implanted oxygen ions is less than the amount of implanted oxygen ions for the conventional epitaxial SIMOX wafer. Oxygen ions are implanted into the surface layer of the silicon wafer from the wafer surface, and after that, the wafer is heat-treated, so that the thinning stop layer of the imperfect buried oxide film is formed along the entire plane of the wafer. Thereby, variation of the thickness of the semiconductor device formed in an active layer can be reduced, since the, the reliability of the accuracy of the end point of silicon wafer thinning is higher than that of a thinning using the conventional deep trench structure as an end point detector.

### BRIEF DESCRIPTION OF THE DRAWINGS

FIG. 1A is a vertical cross-sectional view of a silicon wafer used in a method of manufacturing a semiconductor device according to the example 1 of the present invention.

FIG. 1B is a vertical cross-sectional view of a silicon wafer in a step of ion-implanting, in which oxygen ions are implanted from the surface layer of the silicon wafer, in the method of manufacturing the semiconductor device according to the example 1 of the present invention.

FIG. 1C is a vertical cross-sectional view of a silicon wafer in a step of heat-treating and film forming, in which the ion-implanted layer is heat treated and a thinning stop layer is formed, in the method of manufacturing the semiconductor device according to the example 1 of the present invention.

FIG. 1D is a vertical cross-sectional view of a silicon wafer in a step of heat-treating and film forming, in which an epitaxial film is formed on an active layer, in the method of manufacturing the semiconductor device according to the example 1 of the present invention.

FIG. 1E is a vertical cross-sectional view of a silicon wafer in a step of forming a semiconductor device, in which an imaging sensor is formed in an epitaxial layer, in the method of manufacturing the semiconductor device according to the example 1 of the present invention.

FIG. 1F is a vertical cross-sectional view of a silicon wafer in a step of bonding, in which an adhesive layer is formed on a multilayer inter connection layer, in the method of manufacturing the semiconductor device according to the example 1 of the present invention.

FIG. 1G is a vertical cross-sectional view of a silicon wafer in a step of bonding, in which a base substrate and a support substrate are bonded, in the method of manufacturing the semiconductor device according to the example 1 of the present invention.

FIG. 1H is a vertical cross-sectional view of a silicon wafer in a step of thinning, in which the silicon wafer is dry-etched, in the method of manufacturing the semiconductor device according to the example 1 of the present invention.

FIG. 1I is a vertical cross-sectional view of a silicon wafer in a step of thinning, in which the thinning stop layer is dry-etched, in the method of manufacturing the semiconductor device according to the example 1 of the present invention.

FIG. 1J is a vertical cross-sectional view of the semiconductor device in which a color filter and a micro-lens are formed on the dry etching surface of the silicon wafer in the method of manufacturing the semiconductor device according to the example 1 of the present invention.

FIG. 2 is a graph showing RIE stop capability of the thinning stop layers formed by different dosages of implanted oxygen ions, which corresponds to ⅛ to ½ times of the dosage used in the SIMOX wafer production, in the method of manufacturing the semiconductor device according to the example 1 of the present invention.

### DETAILED DESCRIPTION OF THE INVENTION

Hereinafter, embodiments of the invention will be described in detail.

In a method of manufacturing a semiconductor device of a first embodiment of the present invention, first, oxygen ions are implanted from the surface of a silicon wafer in a step of ion-implanting. An ion-implanted layer is formed in the surface layer of the silicon wafer. In a step of heat-treating and film forming, the ion-implanted layer is heat treated, and an epitaxial film is formed on the surface of the silicon wafer, after the step of ion-implanting. A thinning stop layer having a mixture of silicon grains and a silicon oxide is formed along the entire plane of the silicon wafer by the heat treatment. In addition, an active layer is formed between the surface side of the silicon wafer and the thinning stop layer. After that, in a step of forming a semiconductor device, a semiconductor device is formed in the epitaxial film. Next, in a step of bonding, a support substrate is bonded to the surface of the epitaxial film to produce a bonded wafer. After bonding, in a step of thinning, the silicon wafer is thinned from a back side of the silicon wafer, by at least one of grinding, polishing, and wet-etching until the remaining thickness thereof is 10 to 100 μm, and then further thinned by thy-etching as a finishing process.

According to the method of manufacturing the semiconductor device of the first embodiment of the present invention, in the step of ion-implanting, the amount of oxygen ions implanted into the surface layer of the silicon wafer is less than that for the production of a conventional epitaxial SIMOX wafer, and the heat treatment (annealing) of the ion-implanted layer after the step of ion-implanting is performed by the heat-treating at a lower temperature than that for the high-temperature annealing of the epitaxial SIMOX wafer production. Thus, the thinning stop layer is formed in the surface layer of the silicon wafer along the entire plane of the wafer. As a result, variation of the thickness of the semiconductor device formed in an active layer can be reduced, since the, the reliability of the accuracy of the end point of silicon wafer thinning is higher than that of a thinning using the conventional deep trench structure as an end point detector.

After that, a semiconductor device is formed in the epitaxial film, and next, a support substrate is bonded to the surface of the epitaxial film, to thereby produce the bonded wafer. After bonding, in a step of thinning, the silicon wafer is thinned from a back side of the silicon wafer, by at least one of grinding, polishing, and wet-etching until the remaining thickness thereof is 10 to 100 μm, such as 10 to 30 μm, and then further thinned by dry-etching as a finishing process.

For example, a backside illuminated solid-state imaging sensor and the like could be formed, as the semiconductor device.

“The surface layer of the silicon wafer” in the present specification means a layer having a depth ranging from 0.05 to 0.5 μm from the surface of the silicon wafer. When the depth of the thinning stop layer is less than 0.05 μm, defects on the surface of the silicon wafer increase. In addition, when the depth of the thinning stop layer exceeds 0.5 μm, a special ion implantation system with a higher ion implantation energy is required, since the ion implantation energy of the commercially available ion implantation systems is not enough.

“The entire plane of the wafer” means the area where flattening is applied on the silicon wafer at least. Therefore, the thinning stop layer is formed without a gap over the entire area, in the area in which flattening of the surface layer of the wafer is applied below the active layer.

A single-crystal silicon wafer can be used as the silicon wafer. The surface of the silicon wafer is mirror-finished. The diameter of the silicon wafer is, for example, 200 mm, 300 mm, 450 mm or the like.

An epitaxial silicon wafer is obtained by forming the epitaxial film on the silicon wafer. The epitaxial silicon wafer is analogous to the epitaxial SIMOX wafer through performing the heat treatment after implantation of oxygen ions. However, this epitaxial silicon wafer is a wafer distinct from the epitaxial SIMOX wafer due to the existence of the buried oxide film. More specifically, the thinning stop layer, which is an imperfect buried oxide film, is embedded in the surface layer of the silicon wafer, in the epitaxial silicon wafer used in the present invention.

“The thinning stop layer (imperfect buried oxide film)” means an imperfect silicon oxide film, which is embedded in the surface layer of the silicon wafer and has a mixture of silicon oxides, which are precipitated oxides or oxides in band-like form made of SiOₓ including SiO₂, and silicon grains, which are silicon in the silicon wafer granulated by implantation of the oxygen ions, at a predetermined ratio. “The imperfect silicon oxide film” means a film having small pieces of the silicon oxides discontinuously (intermittently) formed in the whole ion-implanted layer (portion into which oxygen ions are implanted).

The thickness of the thinning stop layer is in a range of 0.05 to 0.5 μm. When the thickness of the thinning stop layer is less than 0.05 μm, the thinning stop layer does not function sufficiently as an end point detector in the step of thinning the silicon wafer. In addition, when the thickness of the thinning stop layer exceeds 0.5 μm, it takes a long period of time to implant the oxygen ions. Consequently, the productivity of the epitaxial wafer decreases, and the production cost increases.

Ion implantation methods of a SIMOX process of any of a low-energy method (100 keV or less), a low-dose method, and a modified low-dose method may be used in the step of ion-implanting.

The temperature for heating of the wafer during oxygen ion-implanting is in a range of, for example, 200° C. to 600° C. When the heating temperature is less than 200° C., large damages formed during oxygen ion-implanting into the surface layer of the wafer remain and cannot be removed. In addition, when the heating temperature exceeds 600° C., the amount of degassing from the ion implantation system increases.

The implantation energy of oxygen is in a range of 20 to 220 keV. When the implantation energy is less than 20 keV, defects on the surface of the silicon wafer are enlarged. In addition, when the implantation energy exceeds 220 keV, a special ion implantation system with a higher ion implantation energy is required, since the ion implantation energy of the commercially available ion implantation systems is not enough.

The amount of implanted oxygen ions is in a range of 1×10¹⁵ atoms/cm² to 4×10¹⁷ atoms/cm². When the amount of oxygen ions implanted in the step of ion-implanting is less than 1×10¹⁵ atoms/cm², the thinning stop layer does not function as an end point detector in the step of thinning the silicon wafer. In addition, when the amount exceeds 4×10¹⁷ atoms/cm², it takes a long period of time to implant the oxygen ions. Consequently, the productivity of the epitaxial wafer decreases, and the production cost increases.

The depth of implanted oxygen ions is in a range of 0.05 to 0.5 μm. The implantation of the oxygen ions may be performed only once, or may be performed several times. In addition, when the implantation thereof is performed several times, the oxygen ions may be implanted with different levels of implantation energy.

The heating temperature of the wafer in the heat-treating of the step of heat-treating and film forming, where the thinning stop layer is formed, is in a range of 900° C. to 1200° C. When the heat treatment temperature is lower than 900° C., the amount of precipitated oxygen is low. In addition, when the heat treatment temperature exceeds 1200° C., a special annealing furnace for ultra-high temperature heat treatment is needed. The heat treatment temperature of the silicon wafer is preferably in a range of 1100° C. to 1200° C.

Time for the heat-treating of the step of heat-treating and film forming is in a range of 30 seconds to 4 hours. When the heat treatment time is less than 30 seconds, the amount of precipitated oxygen is low. In addition, when the heat treatment time exceeds 4 hours, the productivity of the epitaxial wafer decreases, and the production cost increases. The preferable time for heat-treating the silicon wafer ranges from 5 minutes to 4 hours. An even more preferable time for heat-treating the silicon wafer ranges from 10 minutes to 1 hour.

Single crystal silicon can be used as a material of the epitaxial film formed by epitaxial growth. In general, the type of epitaxial growth includes a vapor phase epitaxy (VPE) method, a liquid phase epitaxy (LPE) method, and a solid phase epitaxy (SPE) method. Particularly, for the epitaxial growth of silicon, a chemical vapor deposition (CVD) method is mainly adopted in view of the degree of crystallinity of the grown crystal, mass the productivity, and simple construction of the apparatus, and to facilitate the assembly of the apparatus.

The epitaxial growth of silicon by the CVD method is performed by introducing a source gas including, for example, silicon together with a carrier gas (typically H₂ gas) into a reacting furnace, and depositing silicon created by thermal decomposition or reduction of a raw material gas on the silicon single-crystal substrate (produced by a CZ method), which is heated at a high temperature of 1000° C. or higher. From many compounds including silicon, the following four compounds, SiH₄, SiH₂Cl₂, SiHCl₃, and SiCl₄ are normally used in view of purity, reaction rate, ease of handling and the like.

A high-frequency induction heating type or a lamp heating type and the like, can be used as an epitaxial growth furnace.

The thickness of the epitaxial film is in a range of 1 to 20 μm. When the thickness is less than 1 μm, a device cannot be formed in the epitaxial film. In addition, when the thickness exceeds 20 μm, the productivity of the epitaxial wafer decreases, and the production cost increases.

The temperature for the epitaxial growth (heat-treating temperature of the wafer) is in a range of 1000° C. to 1200° C. When the temperature is less than 1000° C., the degree of crystallinity of the epitaxial film is reduced. In addition, when the temperature exceeds 1200° C., a slip can easily occur.

Time for the epitaxial growth (time for heat-treating of the wafer) is in a range of 1 minute to 20 minutes. When the time is shorter than one minute, an epitaxial film with a predetermined thickness cannot be obtained. In addition, when the time exceeds 20 minutes, slip occurs easily.

As a thinning method before thinning as a finishing process of the silicon wafer, any one method of grinding, polishing, and wet etching may be chosen. In addition, any combination of two methods selected from these may be chosen. In addition, the all three thinning methods may be used, before the final thinning. When a plurality of thinning methods are combined, the order of application of the methods is arbitrary.

In grinding, the back side (surface on the side opposite to the bonding surface) of the silicon wafer may be coarsely grinded by, for example, a resinoid grinding wheel #320, and subsequently may be finish-grinded by a resinoid grinding wheel #2000.

In polishing, a known polishing apparatus for finish polishing the surface of the wafer is used. As a polishing cloth, a nonwoven fabric, which is used for finish polishing and has a form surface layer formed on the surface of a flexible plastic foam. The amount of polishing is in a range of 0.1 to 2 μm.

In wet-etching, a HF/HNO₃/CH₃COOH solution or an alkaline solution (for example, KOH) is brought into contact with the back side of the silicon wafer.

Before the final thinning of dry-etching as a finishing process of the wafer, the wafer is thinned until the remaining thickness of the silicon wafer to be 10 to 100 μm, such as 10 to 30 μm. As methods of measuring the remaining thickness of the silicon wafer layer, for example, a FTIR method, an optical interferometry method, an ellipsometry method or the like, can be used.

As a method for dry-etching of the silicon wafer, reactive ion etching (RIE), for example, can be used. In addition, ion beam etching, reactive ion beam etching, reactive laser beam etching, reactive gas etching and the like can be used.

In the step of heat-treating and film forming of the method of manufacturing the semiconductor device of the first embodiment of the present invention, heat-treating of the ion-implanted layer and forming of the epitaxial film can be simultaneously performed. In addition, it is also possible to perform the forming of the epitaxial film after the heat-treating of the ion-implanted layer. In addition, it is also possible to perform the forming of the epitaxial film before the heat-treating of the ion-implanted layer.

When the heat-treating is performed after the step of ion-implanting, and then the forming of the epitaxial film is performed, precipitated oxygens by the heat treatment function as gettering sites. Therefore, a high-quality epitaxial film can be formed.

A semiconductor device which is a second embodiment of the invention includes: a silicon wafer; a thinning stop layer having a mixture of silicon grains and a silicon oxide, formed in the surface layer of the silicon wafer along the entire plane of the wafer by implanting oxygen ions into the silicon wafer from the surface thereof, and then heat-treating the silicon wafer; an active layer formed between the surface side of the silicon wafer and the thinning stop layer; an epitaxial film formed on the surface of the active layer; a semiconductor device formed in the epitaxial film; and a support substrate bonded to the surface of the epitaxial film, wherein the silicon wafer and the thinning stop layer are thinned from a back side of the silicon wafer, by at least one of grinding, polishing, and wet-etching until a remaining thickness thereof to be 10 to 100 μm, and then further thinned by dry-etching as a finishing process.

According to the semiconductor device of the second embodiment of the present invention, the thinning stop layer is formed in the surface layer of the silicon wafer, on which the epitaxial film is formed, along the entire plane of the wafer, by ion-implanting of oxygen from the wafer surface and the subsequent heat-treating. The thinning stop layer is an imperfect buried oxide film having a mixture of silicon grains and the silicon oxides. For this reason, the, the reliability of the accuracy of the end point of silicon wafer thinning is higher than that of a thinning using the conventional deep trench structure as an end point detector. As a result, it is possible to manufacture a semiconductor device in which variations in the thickness of the semiconductor device are reduced.

Hereinafter, examples of the invention will be described in detail.

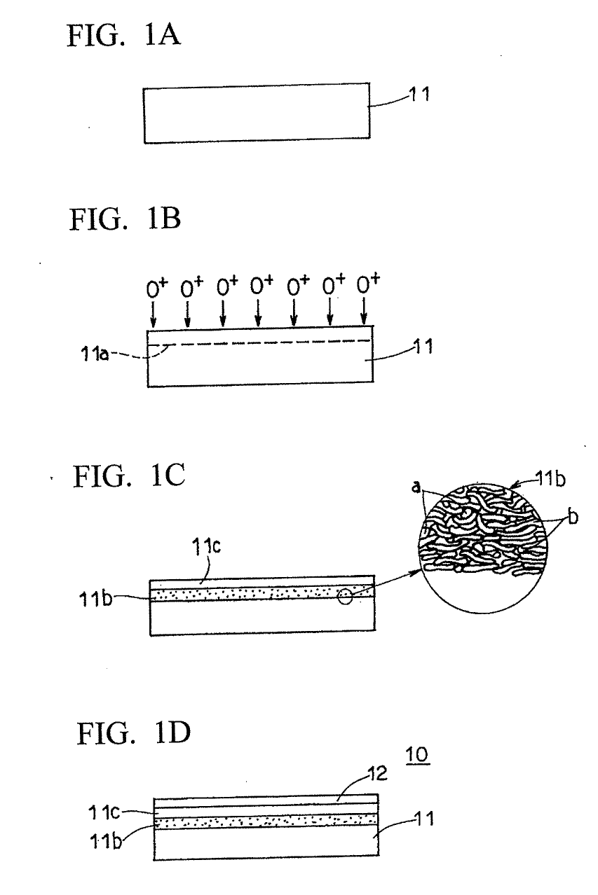

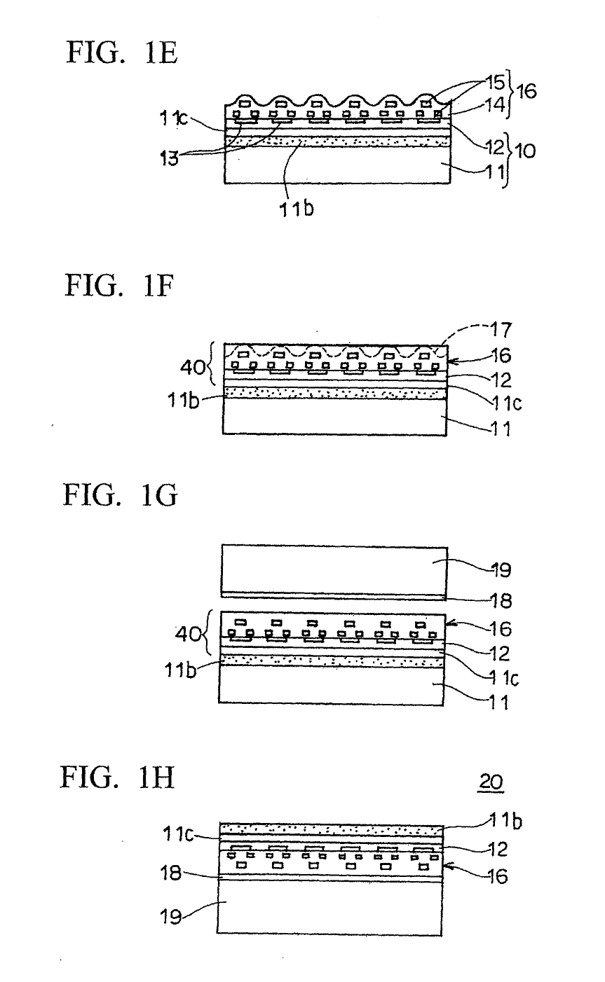

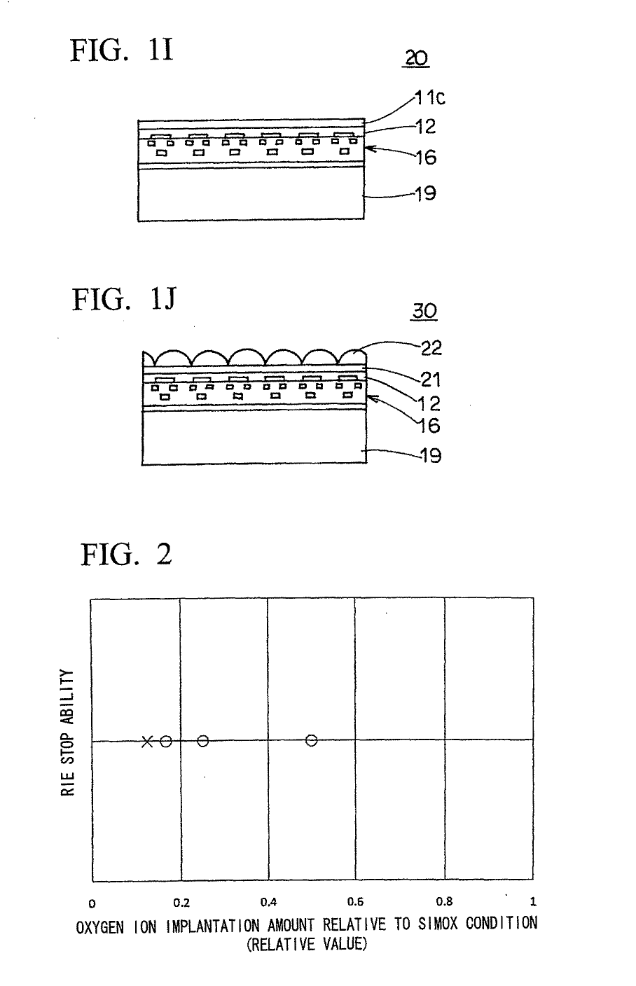

A method of manufacturing a backside illuminated solid-state imaging sensor in which the method of manufacturing the semiconductor device according to the example 1 of the present invention is used, is described using FIGS. 1A to 1J.

First, a base substrate 11 was prepared (FIG. 1A). This was a silicon wafer whose diameter was 300 mm, the thickness was 775 the axial orientation of the main surface was <100>, and the specific resistance to boron doping was 1.0 Ω·cm.

The base substrate 11 was produced by sequentially performing the following processes. First, a silicon single crystal was pulled by the CZ method from a silicon melt within a crucible. Then it was block cut, and ground at its circumference. Then, the silicon single crystal was sliced into a number of wafers by a wire saw. Then, each wafer was chamfered, wrapped, etched, polished, and cleaned.

Next, in a step of ion-implanting, oxygen ion was implanted from the surface of the base substrate 11, forming an ion-implanted layer 11a in the surface layer of the base substrate 11 (FIG. 1B). After the step of ion-implanting, in a step of heat-treating and film forming, the ion-implanted layer 11a in the base substrate 11 was heat-treated in a predetermined heating condition, and an epitaxial film 12 was grown on the surface of the base substrate 11 by putting the base substrate 11 into a chamber of an epitaxial growth system. By heat-treating the ion-implanted layer 11a, a thinning stop layer (imperfect buried oxide film) 11b having a mixture of silicon grains a and silicon oxides b was formed (FIG. 1C). At the same time, an active layer 11c was formed between the surface side of the silicon wafer and the thinning stop layer (FIG. 1D).

In the step of ion-implanting, the base substrate 11 was put into an ion implantation system, where a heating temperature of the wafer was set to 400° C., and oxygen ions were ion-implanted into the surface layer of the base substrate 11 from the wafer surface at 200 keV and 1.3×10¹⁷ atoms/cm². As a result, the ion-implanted layer 11a, which was made of lower oxides, such as SiO and Si₂O₃, was formed at a depth of about 0.4 μm from the surface of the base substrate 11.

The heat-treating of the base substrate 11 in the step of heat-treating and film forming was performed in argon gas atmosphere at 1200° C. for 30 minutes. As a result, the immature ion-implanted layer 11a was converted to the authentic thinning stop layer 11b by the heat-treating. The thinning stop layer 11b had a thickness of 0.2 μm and included a mixture of the silicon oxide b, such as a precipitated oxide or a belt-like oxide made of SiOₓ including SiO₂, and the silicon grains a, where silicon in the base substrate 11 was granulated by the ion implantation of oxygen, at a predetermined ratio. In addition, the active layer 11c having a thickness of 0.4 μm was formed between the surface side of the base substrate 11 and the thinning stop layer 11b.

At this time, since the active layer 11c and the epitaxial film 12 were made of the same silicon, they were integrated. As an alternative, it is possible to skip the heat-treating and to form the thinning stop layer 11b by heating the ion-implanted layer 11a in the subsequent film forming where an epitaxial film 12 is formed on the surface of the base substrate 11. As another alternative, it is possible to heat-treat the ion-implanted layer 11a after film forming of the epitaxial film 12, in the same condition shown in the FIG. 1C.

In epitaxial growing in the step of heat-treating and film forming, the base substrate 11 was disposed within a reaction chamber of a single wafer type vapor phase epitaxial growth system, and the epitaxial film 12 was grown on the surface of the base substrate 11 by a vapor phase epitaxial method.

In the vapor phase epitaxial growth system, a susceptor with circular shape as a plan view was disposed in the middle of a chamber in which heaters were arranged at the top and bottom. In the middle of the front surface of the susceptor, there was a wafer accommodating portion having a concave shape for accommodating the base substrate 11 in a state where both sides thereof were horizontally and transversely disposed. In addition, a pair of gas supply ports for flowing a predetermined carrier gas (H₂ gas) and a predetermined source gas (SiHCl₃ gas) parallel to the wafer surface, were provided in the upper space of the chamber on one of side portions of the chamber. In addition, an exhaust port of the two gases was provided on the other side portion of the chamber.

During epitaxial growing, first, the base substrate 11 was mounted in the wafer accommodating portion of the susceptor in a state where both sides of the wafer were horizontally disposed. Next, the carrier gas and the source gas were introduced into the reaction chamber through the corresponding gas supply ports. The pressure within the furnace was set to 0.1 KPa, and silicon generated by thermal decomposition or reduction of the source gas was deposited on the base substrate 11 heated at a high temperature of 1100° C., at a reaction rate of 2 μm/minute. As a result, the epitaxial film 12 of the silicon single crystal having a thickness of 5 μm was grown on the surface of the base substrate 11. In the way described above, an epitaxial silicon wafer 10 was produced.

Next, photodiodes 13 were formed in the epitaxial film 12 (FIG. 1E). In the photodiode 13, three parts were arranged in the following order from the surface side of the epitaxial film 12 into the thickness direction, a pixel separation region part of an imaging region, a semiconductor well region part, and a photo sensor. In particular, the photodiodes 13 and a plurality of MOS transistors were formed in the imaging region section of the epitaxial film 12, corresponding to each pixel region section, and CMOS transistors were formed in a peripheral circuit section of the peripheral region. Further, a multilayer interconnection layer 16, in which multilayer interconnections 15 were buried in an interlayer insulating film 14, was formed on the surface of the epitaxial film 12.

Next, an adhesive layer 17, which was a silicon oxide film, was formed in the surface of the bonding interface side of the multilayer interconnection layer 16 (FIG. 1F). A CMOS type solid-state imaging sensor (semiconductor device) 40 was formed from the epitaxial film 12, in which the photodiodes 13 and the like were formed, and the multilayer interconnection layer 16.

After that, chemical mechanical polishing was performed on the surface of the adhesive layer 17, and flatness of the surface of the bonded adhesive layer 17 was enhanced.

Next, a support substrate 19 made of a single-crystal silicon wafer was bonded to the surface of the multilayer interconnection layer 16 formed on the base substrate 11 (FIG. 1G).

In this case, first, the support substrate 19 under which another adhesive layer 18 made of a silicon oxide film was formed, was prepared on the surface bonded to the multilayer interconnection layer 16. The support substrate 19 used above had the same specifications to the base substrate 11.

Specifically, in the bonding method applied, the surfaces of the adhesive layers 17 and 18 were contacted each other at room temperature first. Then, the multilayer interconnection layer 16 and the support substrate 19 were bonded, resulting in a bonded wafer 20. After that, the bonded wafer 20 was put into a thermal oxidation furnace, and bonding strength was enhanced by performing the bonding and heat treatment.

Next, the bonded wafer 20 was turned over, grinding and polishing were sequentially performed on the base substrate 11 from the side opposite to the bonded side thereof. Then, the base substrate 11 was thinned until the remaining thickness to be 20 μm. Then the base substrate 11 was removed by performing reactive ion etching (thy-etching) as a finishing process (FIG. 1H). At the time of grinding, the base substrate 11 was ground from the device forming surface side by resinoid grinding wheels from #360 to #2000. The remaining thickness after grinding was 22 μm or so. At the time of polishing, the bonded wafer 20 was held in the lower surface of a polishing head of a single wafer type single-side polishing apparatus with the base substrate 11 side directed downward. Next, the polishing head rotating at 60 rpm was gradually moved downward, and the grinding surface of the base substrate 11 was polished at a predetermined polishing pressure by pressing it to a polishing cloth on a polishing platen rotating at 60 rpm. The polishing cloth was Suba600 (Asker hardness of 80) which was a soft nonwoven fabric pad made by Rodale Corporation. The amount of polishing was 2 μm. Further, the conditions of reactive ion etching were as follows: the reaction gas was a CF₄/CHF₃/He gas, the gas flow rate per minute was 50 cm³/50 cm³/200 cm³, the high-frequency output was 1000 W, the reaction pressure was 0.3 Torr, and the etching rate was 200 nm/min.

Next, the thinning stop layer was removed by immersing the bonded wafer 20 in an HF solution having an HF concentration of 5 wt. % for ten minutes (FIG. 1I). As a result, the active layer 11c was exposed.

Next, a silicon nitride film and a silicon oxide film, for example, which become passivation films, were formed on the exposed surface of the active layer 11c by a plasma CVD method.

Next, an opening for leading-out a pad (terminal), which forms connection to the multilayer interconnection 15, was provided at necessary portion of a solid-state imaging sensor forming region of the active layer 11c. Then, a pad was provided through this opening.

After that, color filters 21 of corresponding colors were formed at a position corresponding to each photodiode 13, and micro-lenses 22 were further formed thereon. Thereby, a backside illuminated solid-state imaging sensor (semiconductor device) 30 was manufactured (FIG. 1J).

As seen from the above, the amount of implanted oxygen ions was less than that of the conventional epitaxial SIMOX wafers. Oxygen ions were implanted into the surface layer of the base substrate 11 from the surface of the wafer. Then, by heat treating the wafer, the thinning stop layer 11b, which was an imperfect buried oxide film, was formed along the entire plane of the wafer. As a result, variation of the thickness of the CMOS type solid-state imaging sensor 40, which was formed in the epitaxial film 12 and integrated with the active layer 11c, could be reduced, since the, the reliability of the accuracy of the end point of thinning of the base substrate 11 was higher than that of a thinning using the conventional deep trench structure as an end point detector.

Here, a graph of FIG. 2 shows a result of evaluating the RIE stop capability within the wafer surface. The thinning stop layers were formed by different dosages of implanted oxygen ions, which corresponds to ⅛ to ½ times of the dosage used in the conventional SIMOX wafer production (reference value 1). The wafer subjected to the evaluation was the base substrate 11 of the backside illuminated solid-state imaging sensor 30 of the example 1. The amount of implanted oxygen ions of the SIMOX wafer was 2.6×10″ atoms/cm², and the evaluation was performed by cross-section TEM.

As a result, it was shown that there was a lesser extent of surface irregularities of the thinning stop layer in the surface of the wafer, in RIE stop to the thinning stop layers formed by the amount of implanted oxygen ions, corresponding to ½-, ¼-, and ⅙-folds of that used for the conventional SIMOX wafer production and RIE stopped. On the other hand, in RIE stop to the thinning stop layer formed by the amount of implanted oxygen ions corresponding to ⅛-fold, there was a more extent of surface irregularities of the thinning stop layer in the surface of the wafer, and the RIE stop capability was insufficient.

The invention is useful for manufacturing a backside illuminated CMOS image sensor and the like, but is not limited thereto.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of manufacturing a semiconductor device, comprising:
a step of ion-implanting, in which oxygen ions are implanted from a surface of a silicon wafer to form an ion-implanted layer in the surface layer of the silicon wafer;
a step of heat-treating and film forming, in which the ion-implanted layer is heat treated and an epitaxial film is formed on the surface of the silicon wafer, after the step of ion-implanting;
a step of forming a semiconductor device, in which a semiconductor device is formed in the epitaxial film, after the step of heat-treating and film forming;
a step of bonding, in which a support substrate is bonded to the surface of the epitaxial film to produce a bonded wafer, after the step of forming a semiconductor device; and
a step of thinning, in which the bonded wafer is thinned from a back side of the silicon wafer, by at least one of grinding, polishing, and wet-etching until a remaining thickness thereof to be 10 to 100 μm, and then further thinned by dry-etching as a finishing process,
wherein in the step of heat-treating and film forming, a thinning stop layer having a mixture of a silicon grain and a silicon oxide is formed along an entire plane of the wafer, and an active layer is formed between a surface side of the silicon wafer and the thinning stop layer.

2. The method of manufacturing the semiconductor device according to claim 1, wherein in the step of heat-treating and film forming, the epitaxial film is formed after the heat treatment of the ion-implanted layer.

3. The method of manufacturing the semiconductor device according to claim 1, wherein in the step of heat-treating and film forming, the heat treatment of the ion-implanted layer and the formation of the epitaxial film are performed concurrently.

4. The method of manufacturing the semiconductor device according to claim 1, wherein in the step of heat-treating and film forming, the ion-implanted layer is heat-treated after an epitaxial film is formed.

5. The method of manufacturing the semiconductor device according to claim 1, wherein in the step of ion-implanting, the silicon wafer is heated at a temperature of 200° C. or higher, and the amount of implanted oxygen ions is in a range of 1×10¹⁵ atoms/cm² to 4×10¹⁷ atoms/cm².

6. The method of manufacturing the semiconductor device according to claim 1, wherein in the step of heat-treating and film forming, the silicon wafer is heat-treated at a temperature of 900° C. to 1200° C. for a time of thirty seconds to four hours.

7. A semiconductor device comprising:
a silicon wafer;
a thinning stop layer, which has a mixture of a silicon grain and a silicon oxide and is formed along an entire plane of the wafer in the surface layer of the silicon wafer, by implanting oxygen ions into the silicon wafer from the surface thereof and then heat-treating the silicon wafer;
an active layer formed between the surface side of the silicon wafer and the thinning stop layer;
an epitaxial film formed on the surface of the active layer;
a semiconductor device formed in the epitaxial film; and
a support substrate bonded to the surface of the epitaxial film,
wherein the silicon wafer is thinned from a back side of the silicon wafer, by at least one of grinding, polishing, and wet-etching until a remaining thickness thereof to be 10 to 100 μm, and then further thinned by dry-etching as a finishing process.
